(19) United States
(12) Patent Application Publication
(10) Pub. No.: US 2024/0349503 A1
(43) Pub. Date: Oct. 17, 2024

(54) MEMORY DEVICE

(71) Applicant: SK hynix Inc., Icheon-si Gyeonggi-do (KR)

(72) Inventors: Won Geun CHOI, Icheon-si Gyeonggi-do (KR); Rho Gyu KWAK, Icheon-si Gyeonggi-do (KR); Jung Shik JANG, Icheon-si Gyeonggi-do (KR); Seok Min CHOI, Icheon-si Gyeonggi-do (KR)

(73) Assignee: SK hynix Inc., Icheon-si Gyeonggi-do (KR)

(21) Appl. No.: 18/473,764

(22) Filed: Sep. 25, 2023

(30) Foreign Application Priority Data
Apr. 17, 2023 (KR) 10-2023-0050070

(51) Int. Cl. H10B 43/27

(52) U.S. Cl. CPC H10B 43/27

(57) ABSTRACT

There are provided a memory device and a manufacturing method of a memory device. The memory device includes a plurality of conductive layers, support structures penetrating the plurality of conductive layers, a contact hole exposing any one of the plurality of conductive layers and any one of the plurality of support structures, and a contact disposed in the contact hole.

### CROSS-REFERENCE TO RELATED APPLICATION

The present application claims priority under 35 U.S.C. § 119(a) to Korean patent application number 10-2023-0050070 filed on Apr. 17, 2023, in the Korean Intellectual Property Office, the entire disclosure of which is incorporated by reference herein.

### BACKGROUND

### 1. Technical Field

The present disclosure generally relates to a memory device and a manufacturing method of a memory device, and more particularly, to a three-dimensional memory device and a manufacturing method of a three-dimensional memory device.

### 2. Related Art

A memory device may be classified as a volatile memory device in which stored data disappears when the supply of power is interrupted or a nonvolatile memory device in which stored data is retained even when the supply of power is interrupted.

A nonvolatile memory device may include NAND flash memory, NOR flash memory, resistive random-access memory (ReRAM), phase-change random-access memory (PRAM), magnetoresistive random-access memory (MRAM), ferroelectric random-access memory (FRAM), spin transfer torque random-access memory (STT-RAM), or the like.

A memory device along with a controller configured to control the memory device may constitute a memory system. The memory device may include a memory cell array configured to store data and a peripheral circuit configured to perform a program, read, or erase operation in response to a command transmitted from the controller.

The memory cell array may include a plurality of memory blocks, and each of the plurality of memory blocks may include a plurality of memory cells.

Various methods have been sought to minimize various defects occurring when manufacturing memory devices.

### SUMMARY

In an embodiment of the present disclosure, a memory device includes: a gate stack structure including a plurality of insulating layers and a plurality of conductive layers, which are alternately stacked; a plurality of support structures extending in a stacked direction, the stacked direction being a direction in which the plurality of insulating layers and the plurality of conductive layers are stacked; a plurality of contact holes penetrating at least one of the plurality of conductive layers and the plurality of insulating layers, the plurality of contact holes, extending in the stacked direction, being formed to have different lengths to individually expose the plurality of conductive layers disposed at different levels; and a plurality of contacts disposed in the plurality of contact holes, to be individually connected to the plurality of conductive layers, wherein the plurality of contact holes include a first contact hole exposing a sidewall of at least one of the plurality of support structures and a second contact hole that is spaced apart from the plurality of support structures.

In an embodiment of the present disclosure, a memory device includes: a gate stack structure including a plurality of insulating layers and a plurality of conductive layers, which are alternately stacked; a plurality of support structures penetrating the plurality of insulating layers and the plurality of conductive layers; a first contact conductive layer in contact with a conductive layer, among the plurality of conductive layers; and a first contact insulating layer surrounding a sidewall of the first contact conductive layer, wherein the plurality of support structures include a first support structure in contact with the first contact insulating layer.

In an embodiment of the present disclosure, a method of manufacturing a memory device includes: alternately stacking a plurality of first material layers and a plurality of second material layers on a lower structure; forming a plurality of holes that penetrate the plurality of first material layers and the plurality of second material layers; forming a plurality of support structures in the plurality of holes; forming a plurality of contact holes disposed between the plurality of support structures; and forming a plurality of contacts in the plurality of contact holes, wherein the plurality of contact holes include a first contact hole exposing a support structure, among the plurality of support structures, and a second contact hole that is spaced apart from the plurality of support structures.

### BRIEF DESCRIPTION OF THE DRAWINGS

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout the drawings.

FIG. 1 is a diagram illustrating a memory device in accordance with an embodiment of the present disclosure.

FIG. 2 is a diagram illustrating an arrangement structure of a memory cell array and a peripheral circuit, which are shown in FIG. 1.

FIG. 3 is a diagram illustrating the memory cell array shown in FIG. 2.

FIG. 4 is a view illustrating a layout of a memory device in accordance with an embodiment of the present disclosure.

FIG. 5 is a view illustrating sections of the memory device shown in FIG. 4.

FIG. 6 is a view illustrating a layout of a memory device in accordance with an embodiment of the present disclosure.

FIGS. 7A and 7B are views illustrating a layout and a section of a memory device in accordance with an embodiment of the present disclosure.

FIGS. 8A and 8B are views illustrating layouts of a memory device in accordance with embodiments of the present disclosure, and FIG. 9 is a view illustrating a section of the memory device shown in FIG. 8A or 8B.

FIGS. 10A to 10D are views illustrating layouts of a memory device in accordance with embodiments of the present disclosure.

FIGS. 11A to 11I are views illustrating a manufacturing method of a memory device in accordance with an embodiment of the present disclosure.

FIG. 12 is a diagram illustrating a Solid-State Drive (SSD) system to which the memory device of the present disclosure is applied.

FIG. 13 is a diagram illustrating a memory card system to which the memory device of the present disclosure is applied.

### DETAILED DESCRIPTION

The specific structural or functional descriptions disclosed herein are merely illustrative for the purpose of describing embodiments according to the concept of the present disclosure. The embodiments according to the concept of the present disclosure can be modified in various forms and replaced with other equivalent embodiments. Thus, the present disclosure should not be construed as limited to the embodiments set forth herein.

It will be understood that, although the terms “first,” “second,” etc. may be used herein to describe various elements, these elements should not be limited by these terms. These terms are only used to distinguish one element from another element, and the order or number of components is not limited by the terms.

It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

Various embodiments of the present disclosure are directed to a memory device and a method of manufacturing a memory device, which can improve structural stability.

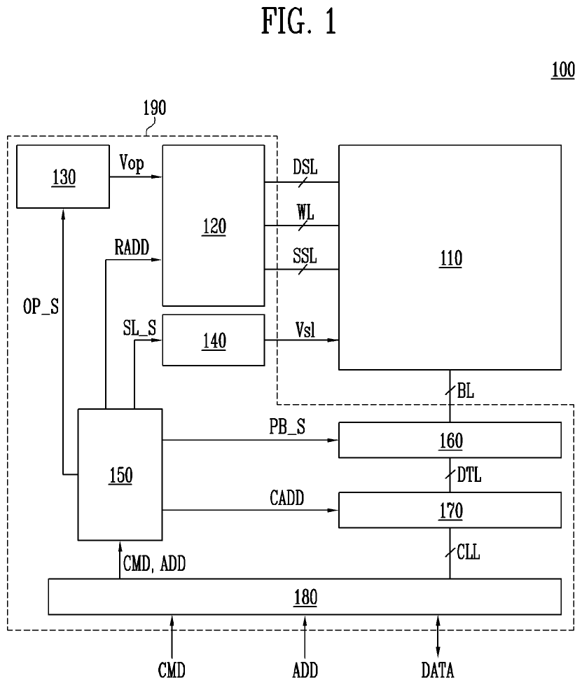

FIG. 1 is a diagram illustrating a memory device in accordance with an embodiment of the present disclosure.

Referring to FIG. 1, the memory device 100 may include a peripheral circuit 190 and a memory cell array 110.

The peripheral circuit 190 may be configured to perform a program operation and a verify operation, which are used to store data, to perform a read operation for outputting data stored in the memory cell array 110, or to perform an erase operation for erasing data stored in the memory cell array 110. The peripheral circuit 190 may include a voltage generating circuit 130, a row decoder 120, a source line driver 140, a control circuit 150, a page buffer 160, a column decoder 170, and an input/output circuit 180.

The memory cell array 110 may include a plurality of memory cells in which data is stored. In an embodiment, the memory cell array 110 may include a three-dimensional memory cell array. The plurality of memory cells may store single-bit data or multi-bit data of two or more bits according to a program manner. The plurality of memory cells may constitute a plurality of cell strings. A plurality of memory cells included in each cell string may be electrically connected to each other through a channel. A plurality of channels of the plurality of cell strings may be connected to the page buffer 160 through a plurality of bit lines BL.

The voltage generating circuit 130 may generate various operating voltages Vop used for a program operation, a read operation, or an erase operation in response to an operation signal OP_S. For example, the voltage generating circuit 130 may selectively generate and output the operating voltages Vop including a program voltage, a verify voltage, a pass voltage, a read voltage, an erase voltage, and the like.

The row decoder 120 may be connected to the memory cell array 110 through a plurality of drain select lines DSL, a plurality of word lines WL, and a plurality of source select lines SSL. The row decoder 120 may transfer the operating voltages Vop to the plurality of drain select lines DSL, the plurality of word lines WL, and the plurality of source select lines SSL in response to a row address RADD.

The source line driver 140 may transmit a source voltage Vsl to the memory cell array 110 in response to a source line control signal SL_S. For example, the source voltage Vsl may be transferred to the memory cell array 110 via a source structure connected to the memory cell array 110.

The control circuit 150 may output the operation signal OP_S, the row address RADD, the source line control signal SL_S, a page buffer control signal PB_S, and a column address CADD, in response to a command CMD and an address ADD.

The page buffer 160 may be connected to the memory cell array 110 through the plurality of bit lines BL. The page buffer 160 may temporarily store data DATA received through the plurality of bit lines BL in response to the page buffer control signal PB_S. The page buffer 160 may sense a voltage or current of the plurality of bit lines BL in a read operation.

In response to the column address CADD, the column decoder 170 may transmit data DATA input from the input/output circuit 180 to the page buffer 160 or may transmit data DATA stored in the page buffer 160 to the input/output circuit 180. The column decoder 170 may exchange data DATA with the input/output circuit 180 through column lines CLL and may exchange data DATA with the page buffer 160 through data lines DTL.

The input/output circuit 180 may transfer, to the control circuit 150, a command CMD and an address ADD, which are transferred from an external device (e.g., a controller) connected to the memory device 100 and may output data received from the column decoder 170 to the external device.

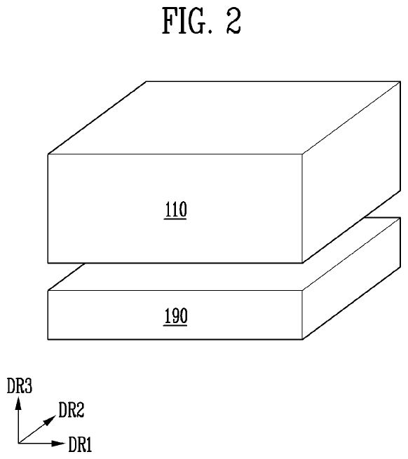

FIG. 2 is a diagram illustrating an arrangement structure of the memory cell array and the peripheral circuit, which are shown in FIG. 1.

Referring to FIG. 2, the memory cell array 110 may overlap with the peripheral circuit 190 in a vertical direction. The peripheral circuit 190 and the memory cell array 110 may be disposed on a first surface of a substrate. The peripheral circuit 190 and the memory cell array 110 may be sequentially disposed in the vertical direction in which the first surface of the substrate faces. Hereinafter, embodiments of the present disclosure will be described by defining a first direction DR1, a second direction DR2, and a third direction DR3. The first surface of the substrate may extend along an XY plane (i.e., DR1-DR2 plane). The first direction DR1 and the second direction DR2 may be defined as directions in which the first surface of the substrate extends. The first direction DR1 and the second direction DR2 may be defined as directions that intersect each other perpendicularly. The third direction DR3 may be defined as a direction that intersects the first surface of the substrate, i.e., the DR1-DR2 plane, perpendicularly and may correspond to the above-described vertical direction.

A process of forming the memory cell array 110 may be performed on a substrate including the peripheral circuit 190. Alternatively, the process of forming the memory cell array 110 and a process of forming the peripheral circuit 190 may be individually performed. The memory cell array 110 and the peripheral circuit 190 may be electrically connected to each other through a process of bonding the memory cell array 110 and the peripheral circuit PC to each other.

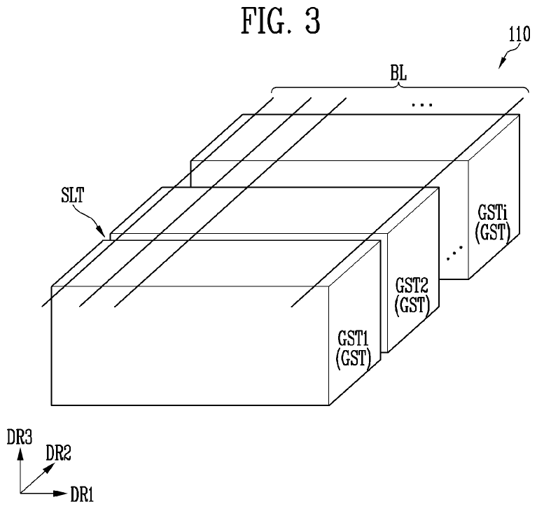

FIG. 3 is a diagram illustrating the memory cell array shown in FIG. 2.

Referring to FIG. 3, the memory cell array 110 may include first to ith gate stack structures GST1 to GSTi (i is a positive integer). The first to ith gate stack structures GST1 to GSTi may be arranged to be spaced apart from each other along the second direction DR2.

A plurality of bit lines BL may extend to overlap with the first to ith gate stack structures GST1 to GSTi. The plurality of bit lines BL may be disposed above or below each of the first to ith gate stack structures GST1 to GSTi. FIG. 3 representatively illustrates an embodiment in which the plurality of bit lines BL are disposed on the first to ith gate stack structures GST1 to GSTi. The plurality of bit lines BL may be spaced apart from each other in the first direction DR1 and may extend in the second direction DR2.

Although not shown in the drawing, a source line may overlap with the first to ith gate stack structures GST1 to GSTi. The first to ith gate stack structures GST1 to GSTi may be disposed between the plurality of bit lines BL and the source line (not shown).

The first to ith gate stack structures GST1 to GSTi may be partitioned by a plurality of slits SLT. The plurality of slits SLT may extend to intersect the plurality of bit lines BL. In an embodiment, the plurality of slits SLT may extend in the first direction DR1. Each slit SLT may be disposed between gate stack structures GST1 and GST2 that are adjacent to each other in the second direction DR2.

Each gate stack structure GST of the memory cell array 110 may include a plurality of conductive layers used as the drain select line DSL, the plurality of word lines WL, and the source select line SSL, which are shown in FIG. 1. Each conductive layer may have a plate-shape extending in the first direction DR1 and the second direction DR2, which intersect each other, from a planar viewpoint. The plurality of conductive layers may be electrically connected to the row decoder 120 of the peripheral circuit 190, shown in FIG. 1, via a plurality of contacts.

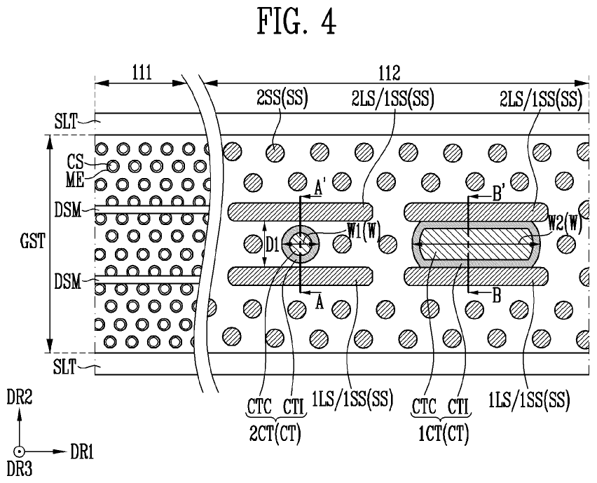

Various methods for ensuring structural stability in a process of forming the memory cell array 110 and simplifying the process have been sought. Hereinafter, a structure of a memory device and a manufacturing method thereof will be described, which can improve the stability of a manufacturing method of a plurality of contacts (e.g., CT shown in FIG. 4) that are connected to each gate stack structure GST.

FIG. 4 is a view illustrating a layout of a memory device in accordance with an embodiment of the present disclosure.

Referring to FIG. 4, a gate stack structure GST of the memory device may extend along the first direction DR1 and the second direction DR2. The gate stack structure GST may include a cell array region 111 and a contact region 112. The contact region 112 of the gate stack structure GST may extend from the cell array region 111. In an embodiment, the contact region 112 of the gate stack structure GST may extend in the first direction DR1 from the cell array region 111.

Slits SLT may be disposed along both sidewalls of the gate stack structure GST. In an embodiment, the slits SLT may extend in the first direction DR1 along both sidewalls of gate stack structures GST that are adjacent to each other in the second direction DR2. Each slit SLT may extend from the cell array region 111 to the contact region 112. The length and width of each slit SLT may be different. The first direction DR1 may be defined as a length direction of the slit SLT, and the second direction DR2 may be defined as a width direction of the slit SLT. For example, a length of the slit SLT in the first direction DR1 may be greater than a width of the slit SLT in the second direction DR2.

A plurality of channel structures CS may be disposed in the cell array region 111 of the gate stack structure GST. In an embodiment, a plurality of channel structures CS extending in the third direction DR3 may be disposed in the cell array region 111 of the gate stack structure GST. The plurality of channel structures CS may be spaced apart from each other in the first direction DR1 and the second direction DR2. Each channel structure CS may be used as a channel region of a cell string and may include a semiconductor material, such as silicon or germanium. The plurality of channel structures CS may be electrically connected to a plurality of bit lines (BL shown in FIG. 3) and a source line (not shown) through a line structure.

A memory layer ME may be interposed between each of the plurality of channel structures CS and the gate stack structure GST. The memory layer ME may include a data storage layer. In an embodiment, a cell string of a NAND flash memory may be defined along each channel structure CS. The memory layer ME may include a blocking insulating layer between the gate stack structure GST and the channel structure CS, a data storage layer between the blocking insulating layer and the channel structure CS, and a tunnel insulating layer between the data storage layer and the channel structure CS. The data storage layer of the NAND flash memory may include a charge trap layer, such as a silicon nitride layer.

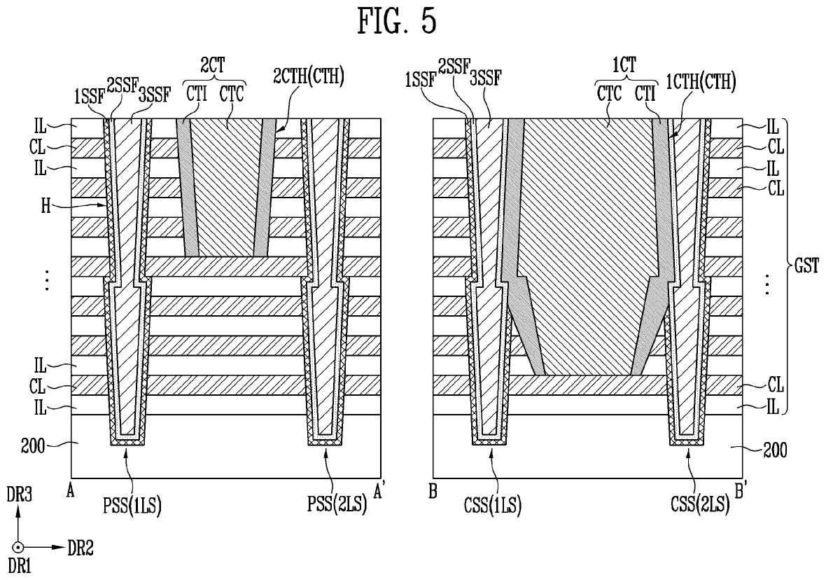

A drain isolation patterns DSM may be disposed in the cell array region 111 of the gate stack structure GST. The drain isolation patterns DSM may extend in the third direction DR3 to penetrate a portion of the gate stack structure GST. In an embodiment, the drain isolation patterns DSM may be formed to a depth that penetrates some of a plurality of stacked layers (e.g., a plurality of insulating layers IL and a plurality of conductive layers CL, which are shown in FIG. 5) of the gate stack structure GST and may be formed to have a shorter length in the third direction DR3 than the slit SLT. The drain isolation patterns DSM may extend in the first direction DR1. The drain isolation patterns DSM may be disposed between slits SLT, the drain isolation patterns DSM being spaced apart from each other. The number and layout of drain isolation patterns DSM arranged between slits SLT may vary. In an embodiment, two or more drain isolation patterns DSM may be arranged between slits SLT while being spaced apart from each other and adjacent to each other in the second direction DR2. In an embodiment, one drain isolation pattern DSM may be arranged between the slits SLT. The plurality of channel structures CS may be arranged at both sides of the drain isolation pattern DSM. The drain isolation pattern DSM may be disposed between channel structures CS that are adjacent to each other in the second direction DR2 or may overlap with some of the plurality of channel structures CS.

A plurality of support structures SS may be disposed in the contact region 112 of the gate stack structure GST. The plurality of support structures SS may be spaced apart from each other in the first direction DR1 and the second direction DR2. The plurality of support structures SS may include at least one of a support structure of a first type 1SS and a support structure of a second type 2SS. The support structure of the first type 1SS may have a linear cross-sectional structure from a planar viewpoint, and the support structure of the second type 2SS may have a circular cross-sectional structure from a planar viewpoint. In an embodiment, the plurality of support structures SS may include a plurality of support structures of the first type 1SS and a plurality of support structures of the second type 2SS. In an embodiment, the plurality of support structures of the first type 1SS may have a linear shape having a length that extends along the first direction DR1.

The plurality of support structures of the first type 1SS may include a plurality of first linear support structures 1LS and a plurality of second linear support structures 2LS. The plurality of first linear support structures 1LS may be arranged to be spaced apart from each other in the first direction DR1. The plurality of second linear support structures 2LS may be arranged to be spaced apart from each other in the first direction DR1. The plurality of second linear support structures 2LS may be parallel to the plurality of first linear support structures 1LS and may be spaced apart from the plurality of first linear support structures 1LS by a first distance D1 in the second direction DR2.

A plurality of contacts CT may be disposed in the contact region 112 of the gate stack structure GST. Each of the plurality of contacts CT may be disposed between a pair of first and second linear support structures 1LS and 2LS corresponding thereto. In an embodiment, a first contact 1CT may be disposed between a first linear support structure 1LS and a second linear support structure 2LS, which face each other and constitute a first pair, and a second contact 2CT may be disposed between a first linear support structure 1LS and a second linear support structure 2LS, which face each other and constitute a second pair.

The plurality of contacts CT may be disposed between the plurality of first linear support structures 1LS and the plurality of second linear support structures 2LS to be spaced apart from each other. In an embodiment, the first contact 1CT and the second contact 2CT may be spaced apart from each other in the first direction DR1.

The plurality of support structures of the second type 2SS may be disposed between the plurality of first linear support structures 1LS and a slit SLT in the second direction DR2, between the plurality of second linear support structure 2LS and a slit SLT in the second direction DR2, and between the plurality of contacts CT in the first direction DR1. A support structure of the second type 2SS, which is adjacent to each contact CT, may be spaced apart from a corresponding contact CT. In other words, the plurality of support structures of the second type 2SS may be disposed to not be in contact with the plurality of contacts CT.

The plurality of contacts CT may have various cross-sectional structures. In an embodiment, the plurality of contacts CT may have a circular cross-sectional structure or may have a bar type cross-sectional structure that extends farther in the first direction DR1 than in the second direction DR2. In an embodiment, the first contact 1CT may have a bar type cross-sectional structure, and the second contact 2CT may have a circular cross-sectional structure.

The support structures of the first type 1SS may suppress the plurality of contacts CT from extending on a plane in a process of forming the plurality of contacts. Thus, each contact CT may be suppressed from extending in the second direction DR2 by a corresponding pair of first and second linear support structures 1LS and 2LS. Accordingly, a width of each contact CT in the second direction DR2 may be limited and may be equal to or less than the first distance D1.

A maximum width W of the plurality of contacts CT may be defined in the first direction DR1 as a length direction of the support structures of the first type1SS. The support structures of the first type 1SS may be formed to have a greater length than the maximum width W of the plurality of contacts CT in the first direction DR1.

The plurality of contacts CT may extend in the third direction DR3 in the contact region 112 of the gate stack structure GST. The plurality of contacts CT may have different lengths in the third direction DR3. The plurality of contacts CT may have different maximum widths W. The maximum width W of the plurality of contacts CT may be proportional to a length with which the plurality of contacts CT extend in the third direction DR3. In an embodiment, the first contact 1CT and the second contact 2CT, among the plurality of contacts CT, may have different lengths in the third direction DR3. Specifically, a length of the first contact 1CT may be longer than a length of the second contact 2CT. A maximum width W2 of the first contact 1CT may be greater than a maximum width W1 of the second contact 2CT.

Some of the plurality of contacts CT may be spaced apart from corresponding pairs of first and second linear support structures 1LS and 2LS, and the rest of the plurality of contacts CT may be in contact with corresponding pairs of first and second linear support structures 1LS and 2LS. In an embodiment, the first contact 1CT may be in contact with the first pair of first and second linear support structures 1LS and 2LS, and the second contact 2CT may be spaced apart from the second pair of first and second linear support structures 1LS and 2LS.

A portion of the different maximum widths W of the plurality of contacts CT may be greater than the first distance D1. In an embodiment, the maximum width W1 of the first contact 1CT may be greater than the first distance D1.

The plurality of contacts CT may be randomly disposed in the contact region 112 of the gate stack structure GST regardless of the lengths thereof or may be disposed in a standardized arrangement. When the plurality of contacts CT are disposed in the standardized arrangement, the arrangement of the plurality of contacts CT may be designed such that the length of the plurality of contacts CT increases or decreases based on their distance from the cell array region 111. In an embodiment, the second contact 2CT may be disposed to be closer to the cell array region 111 compared to the first contact 1CT or may be disposed to be farther from the cell array region 111 compared to the first contact 1CT.

Each of the plurality of contacts CT may include a contact conductive layer CTC and a contact insulating layer CTI surrounding the contact conductive layer CTC. The contact conductive layer CTC may include various conductive materials, such as tungsten. The contact insulating layer CTI may include various insulating materials, such as an oxide layer.

FIG. 5 is a view illustrating sections of the memory device shown in FIG. 4.

Specifically, FIG. 5 illustrates sections of the memory device, taken along lines A-A‘ and B-B’, shown in FIG. 4. Referring to FIG. 5, the gate stack structure GST may include a plurality of insulating layers IL and a plurality of conductive layers CL, which are alternately stacked on a lower structure 200. The lower structure 200 may be a semiconductor substrate including silicon, germanium, and the like, an insulating layer covering a peripheral circuit structure, a source line including a doped semiconductor layer, or an insulating layer penetrating the source line.

The third direction DR3 may be defined as a direction in which the plurality of insulating layers IL and the plurality of conductive layers CL are stacked. Among the plurality of conductive layers CL, at least one conductive layer from a lowermost layer may be used as a source select line, at least one conductive layer from an uppermost layer may be used as a drain select line, and a conductive layer between the source select line and the drain select line may be used as a word line. The drain isolation patterns DSM, shown in FIG. 4, may be formed to a depth that penetrates the conductive layer for the drain select line. The slit SLT, shown in FIG. 4, may be formed to a depth that completely penetrates the plurality of conductive layers CL.

A plurality of contact holes CTH may be disposed in the gate stack structure GST. The plurality of contact holes CTH may penetrate at least one of the plurality of insulating layers IL and the plurality of conductive layers CL. The plurality of contact holes CTH may be formed to different depths to individually expose a plurality of conductive layers CL disposed at different levels. Accordingly, the plurality of conductive layers CL may be individually exposed through the bottoms of the plurality of contact holes CTH. A plurality of contacts CT may be respectively disposed in the plurality of contact holes CTH. In an embodiment, the plurality of contact holes CTH may include a first contact hole 1CTH and a second contact hole 2CTH. A first contact 1CT may be disposed in the first contact hole 1CTH, and a second contact 2CT may be disposed in the second contact hole 2CTH.

Each of the plurality of contact holes CTH may be disposed between a pair of first and second linear support structures 1LS and 2LS corresponding thereto.

Each of the plurality of contact holes CTH may have a smaller width in a lower region that is closer to the lower structure 200 and may have, relatively, a greater width in an upper region that is farther from the lower structure 200. Similarly to the plurality of contacts CT, the maximum width of each of the plurality of contact holes CTH may be increased as a length in the third direction DR3 is lengthened. In an embodiment, the first contact hole 1CTH may be formed to be longer in the third direction DR3 than the second contact hole 2CTH. A maximum width (see W1 shown in FIG. 4) of the first contact hole 1CTH may be greater than a maximum width (see W2 shown in FIG. 4) of the second contact hole 2CTH.

Referring to FIGS. 4 and 5, a plurality of support structures SS may be respectively disposed in a plurality of holes H extending in the third direction DR3 in the gate stack structure GST. Each of the plurality of support structures SS may include a first support structure layer 1SSF. The first support structure layer 1SSF may extend along a surface of a corresponding hole H and may include an insulating material. In an embodiment, the first support structure layer 1SSF may include an oxide layer.

Each of the plurality of support structures SS may include a second support structure layer 2SSF extending along an inner wall of the first support structure 1SSF. The second support structure layer 2SSF may include a material that is different from the material of the first support structure layer 1SSF. In an embodiment, the second support structure layer 2SSF may include a material having an etch selectivity that is different from an etch selectivity of the first support structure layer 1SSF. Also, the second support structure layer 2SSF may include a material having an etch selectivity with respect to material layers stacked in a process of forming the gate stack structure GST. In an embodiment, the second support structure layer 2SSF may include a material having an etch selectivity with respect to a silicon oxide layer and a silicon nitride layer. A metal nitride layer may be used as the second support structure layer 2SSF having the etch selectivity with respect to the silicon oxide layer and the silicon nitride layer. The metal nitride layer may include titanium nitride (TiN) and the like.

Each of the plurality of support structures SS may include a third support structure layer 3SSF extending along an inner wall of the second support structure layer 2SSF. The third support structure layer 3SSF may be disposed in a central region of each support structure SS and may be surrounded by the second support structure layer 2SSF. The third support structure layer 3SSF may include a material that is different from the material of the first support structure layer 1SSF or the second support structure layer 2SSF. In an embodiment, the third support structure layer 3SSF may include a conductive material. For example, the third support structure layer 3SSF may include tungsten and the like.

The first support structure layer 1SSF of each of the plurality of support structures SS includes an insulating material so that the plurality of support structures SS may be insulated from each conductive layer CL.

The first and second linear support structures 1LS and 2LS, as a portion of the plurality of support structures SS, may also include the first to third support structure layers 1SSF to 3SSF.

Referring to FIG. 5, at least one of the plurality of contact holes CTH may be spaced apart from a corresponding pair of first and second linear support structures 1LS and 2LS. At least one of the plurality of contact holes CTH may expose a corresponding pair of first and second linear support structures 1LS and 2LS. In an embodiment, the first contact hole 1CTH may expose a first pair of first and second linear support structures 1LS and 2LS, and the second contact hole 2CTH may be spaced apart from a second pair of first and second linear support structures 1LS and 2LS. The first contact 1CT in the first contact hole 1CTH may be in contact with the first pair of first and second linear support structures 1LS and 2LS through the first contact hole 1CTH. The second contact 2CT in the second contact hole 2CTH may be spaced apart from the second pair of first and second linear support structures 1LS and 2LS with the gate stack structure GST interposed therebetween.

Hereinafter, each of the first and second linear support structures 1LS and 2LS in contact with the at least one of the plurality of contacts CT may be defined as a contact support structure CSS, and each of the first and second linear support structures 1LS and 2LS that are spaced apart from the plurality of contacts CT may be defined as a separation support structure PSS. Accordingly, the contact support structure CSS may be in contact with the first contact 1CT, and the separation support structure PSS may be spaced apart from the second contact 2CT.

A second support structure layer 2SSF of the contact support structure CSS may extend along a portion of an inner wall of the first contact hole 1CTH. The second support structure layer 2SSF of the contact support structure CSS may be exposed through the first contact hole 1CH. A third support structure layer 3SSF of the contact support structure CSS may be disposed to be spaced apart from the first contact 1CT with the second support structure layer 2SSF interposed therebetween.

A first support structure layer 1SSF of the separation support structure PSS may extend along an inner wall of the second contact hole 2CTH.

The first contact hole 1CTH may include an upper region and a lower region. The upper region of the first contact hole 1CTH may be in contact with the contact support structure CSS. The lower region of the first contact hole 1CTH may be spaced apart from the contact support structure CSS.

Because the second support structure layer 2SSF of the contact support structure CSS has an etch selectivity with respect to the material layers (e.g., the silicon oxide layer and the silicon nitride layer) stacked in the process of forming the gate stack structure GST, the second support structure layer 2SSF may be used as an etch barrier when the above-described material layers are etched to form the first contact hole 1CTH. Thus, the second support structure layer 2SSF may suppress the width of the first contact hole 1CTH from being excessively wide.

A contact conductive layer CTC of each of the first contact 1CT and the second contact 2CT may have a bottom surface in contact with a corresponding conductive layer CL. A contact insulating layer CTI of each of the first contact 1CT and the second contact 2CT may surround the contact conductive layer CTC along a sidewall of the contact hole CTH. In an embodiment, a contact insulating layer CTI of the first contact 1CT may extend along a sidewall of the first contact hole 1CTH to be interposed between each of the first and second linear support structures 1LS and 2LS and the contact conductive layer CTC and may extend between a lower portion of the contact conductive layer CTC and a sidewall of the gate stack structure GST. A contact insulating layer CTI of the second contact 2CT may extend along a sidewall of the second contact hole 2CTH to be interposed between a sidewall of the gate stack structure GST and the contact conductive layer CTC. The contact insulating layer CTI may be deposited with a uniform thickness or may be deposited in a tapered shape according to the shape of the sidewall of the contact hole CTH.

The first and second linear support structures 1LS and 2LS, described with reference to FIGS. 4 and 5, may suppress each contact CT from extending in the second direction DR2. Accordingly, a defect in which each contact CT is formed with an excessively large area may be reduced, thereby improving the structural stability of the contact CT. In addition, the plurality of contacts CT may be densely arranged, thereby improving the degree of integration of the memory device.

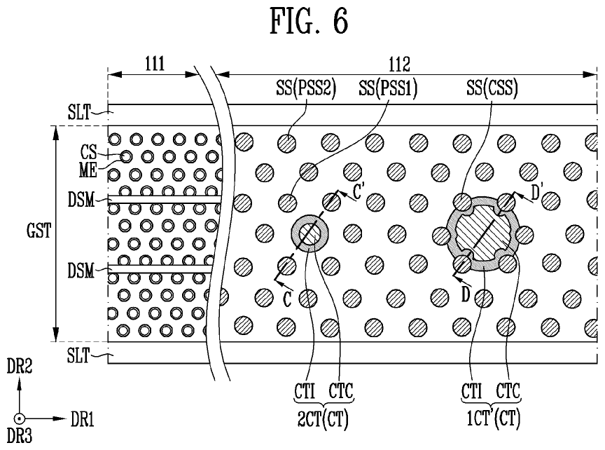

FIG. 6 is a view illustrating a layout of a memory device in accordance with an embodiment of the present disclosure.

Sections of the memory device taken along lines C-C‘ and D-D’, shown in FIG. 6, may be the same as shown in FIG. 5. Hereinafter, overlapping descriptions of components identical to those shown in FIGS. 4 and 5 will be simplified or omitted.

Referring to FIG. 6, a gate stack structure GST of the memory device may be partitioned by a slit SLT and may extend along the first direction DR1 and the second direction DR2, which intersect each other on a plane. The gate stack structure GST may include a plurality of conductive layers CL and a plurality of insulating layers IL, which are alternately stacked in the third direction DR3 on a lower structure 200 as shown in FIG. 5.

A plurality of channel structures CS extending in the third direction DR3 may be disposed in a cell array region 111 of the gate stack structure GST. A memory layer ME may be disposed between each channel structure CS and the gate stack structure GST.

A drain isolation pattern DSM may be disposed in the cell array region 111 of the gate stack structure GST. The drain isolation pattern DSM may be formed to have a shorter length in the third direction DR3 than the slit SLT.

A plurality of support structures SS and a plurality of contacts CT may be disposed in a contact region 112 of the gate stack structure GST. The plurality of support structures SS may extend in the third direction DR3 to penetrate the gate stack structure GST. The plurality of contacts CT may have different lengths in the third direction DR3 and may have different maximum widths from a planar viewpoint. A maximum width of each of the plurality of contacts CT may be proportional to its corresponding length.

The plurality of support structures SS may be formed in the same cross-sectional structure as the support structure of the second type 2SS, which is shown in FIG. 4. The plurality of support structures SS may include a plurality of contact support structures CSS, a plurality of first separation support structures PSS1, and a plurality of second separation support structures PSS2.

Each of the plurality of contacts CT may include a contact conductive layer CTC and a contact insulating layer CTI surrounding the contact conductive layer CTC. The plurality of contacts CT may include a first contact 1CT and a second contact 2CT. The first contact 1CT may be formed longer in the third direction DR3 than the second contact 2CT. A maximum width of the first contact 1CT may be formed to be greater than a maximum width of the second contact 2CT from a planar viewpoint.

The plurality of contact support structures CSS may be in contact with at least one of the plurality of contacts CT, and the plurality of first separation support structures PSS1 and the plurality of second separation support structures PSS2 may be spaced apart from the plurality of contacts CT. The plurality of first separation support structures PSS1 may be spaced apart from each other while surrounding a contact corresponding thereto, and the plurality of second separation support structures PSS2 may be disposed between the plurality of first separation support structures PSS1 and the slit SLT and between the plurality of first separation support structures PSS1 and the plurality of contact support structures CSS.

In an embodiment, the plurality of contact support structures CSS may be disposed to be spaced apart from each other while surrounding the first contact 1CT and may be in contact with the first contact 1CT. The plurality of contact support structures CSS may be disposed to be spaced apart from each other along an outer wall of the contact insulating layer CTI of the first contact 1CT. The plurality of first separation support structures PSS1 may be disposed to be spaced apart from each other while surrounding the second contact 2CT.

Each of the above-described plurality of support structures SS may include the first to third support structure layers 1SSF to 3SSF. A second support structure layer (2SSF shown in FIG. 5) of each of the plurality of contact support structures CSS may be used as an etch barrier, during an etching process to provide a contact hole for the first contact 1CT. Thus, in accordance with the embodiment of the present disclosure, the width of the first contact 1CT, which is formed relatively long, may be suppressed from being excessively wide.

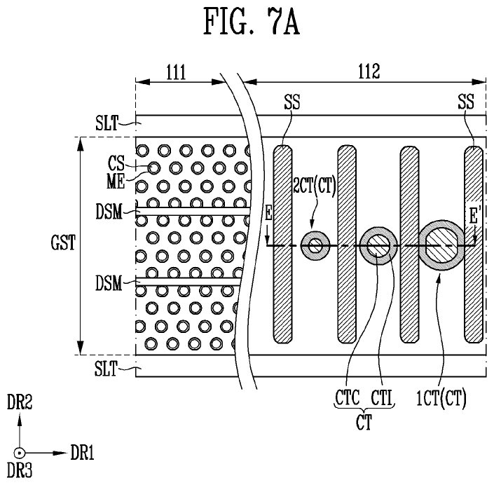

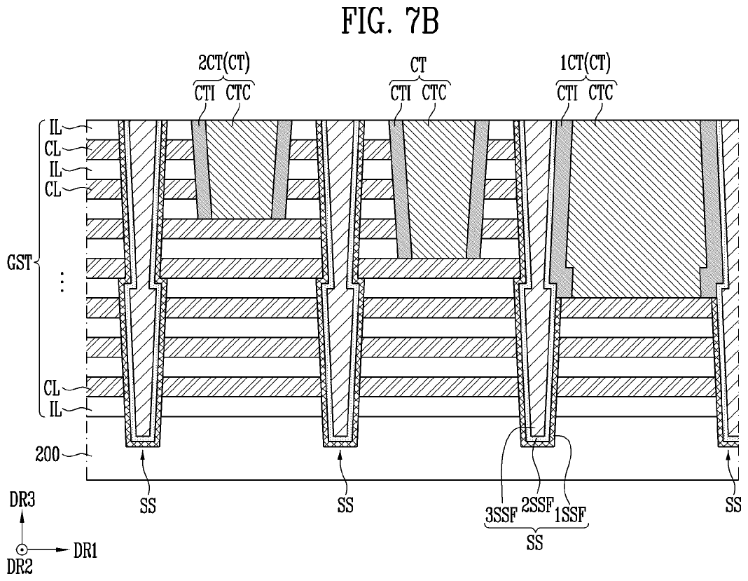

FIGS. 7A and 7B are views illustrating a layout and a section of a memory device in accordance with an embodiment of the present disclosure.

FIG. 7A illustrates a layout of the memory device, and FIG. 7B illustrates a section of the memory device taken along line E-E′ shown in FIG. 7A. Hereinafter, overlapping descriptions of components identical to those shown in FIGS. 4 and 5 will be simplified or omitted.

Referring to FIGS. 7A and 7B, a gate stack structure GST of the memory device may be partitioned by a slit SLT and may extend along the first direction DR1 and the second direction DR2, which intersect each other on a plane. The gate stack structure GST may include a plurality of conductive layers CL and a plurality of insulating layers IL, which are alternately stacked in the third direction DR3 on a lower structure 200.

A plurality of channel structures CS extending in the third direction DR3 may be disposed in a cell array region 111 of the gate stack structure GST. A memory layer ME may be disposed between each channel structure CS and the gate stack structure GST.

A drain isolation pattern DSM may be disposed in the cell array region of the gate stack structure GST. The drain isolation pattern DSM may be formed to be shorter in the third direction DR3 than the slit SLT.

A plurality of support structures SS and a plurality of contacts CT may be disposed in a contact region 112 of the gate stack structure GST. The plurality of support structures SS may extend in the third direction DR3 to penetrate the gate stack structure GST. The plurality of contacts CT may have different lengths in the third direction DR3 and may have different maximum widths from a planar viewpoint. A maximum width of each of the plurality of contacts CT may be proportional to its corresponding length.

The plurality of support structures SS may have a linear cross-sectional structure from a planar viewpoint and may have a line shape having a length in the second direction DR2. The plurality of support structures SS may be arranged to be spaced apart from each other in the first direction DR1.

The plurality of contacts CT and the plurality of support structures SS may be alternately disposed in the first direction DR1. Each of the plurality of contacts may include a contact conductive layer CTC and a contact insulating layer CTI surrounding a sidewall of the contact conductive layer CTC. Each of the plurality of support structures SS may include the first to third support structure layers 1SSF to 3SSF described with reference to FIG. 5. The second support structure layer 2SSF of the support structure SS may be used as an etch barrier, during an etching process to provide a contact hole for each of the plurality of contacts CT. Accordingly, a width of the contact CT in the first direction DR1 may be controlled to be equal to or smaller than a distance between support structures SS that are adjacent to each other in the first direction DR1.

The plurality of contacts CT may include a first contact 1CT and a second contact 2CT. The first contact 1CT may be formed longer in the third direction DR3 than the second contact 2CT. A maximum width of the first contact 1CT may be formed to be greater than a maximum width of the second contact 2CT from a planar viewpoint. The first contact 1CT may be in contact with a support structure SS adjacent thereto, and the second contact 2CT may be spaced part from a support structure SS adjacent thereto. When a contact hole for the first contact 1CT is formed, the width to which the contact hole extends in the first direction DR1 may be suppressed by the second support structure layer 2SSF of the support structure SS.

When the width of each of the plurality of contacts CT is suppressed in the first direction DR1, which is the length direction of the slit SLT, the number of contacts to be disposed in the length direction of the slit SLT in a limited area may be increased. Accordingly, the area occupied by the contact region 112 may be reduced.

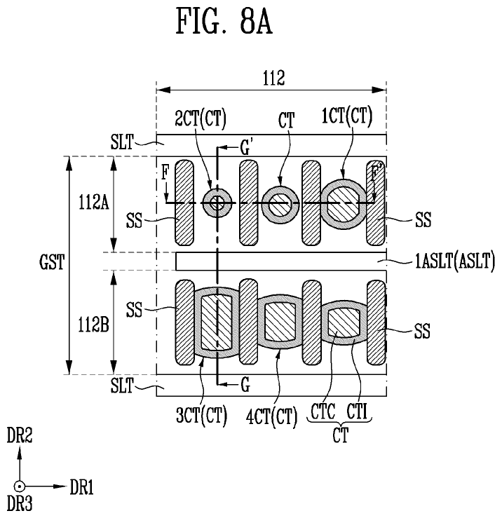

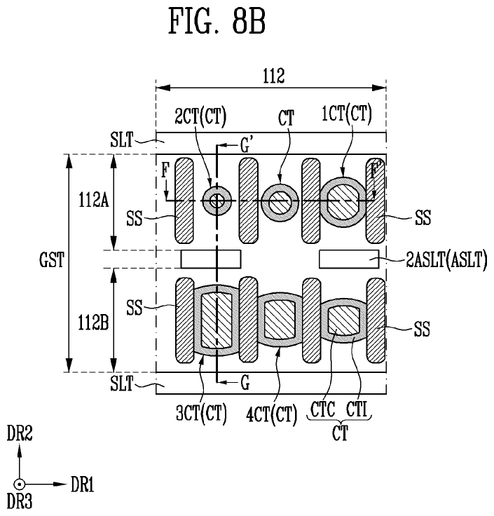

FIGS. 8A and 8B are views illustrating layouts of a memory device in accordance with embodiments of the present disclosure, and FIG. 9 is a view illustrating a section of the memory device shown in FIG. 8A or 8B.

A section of the memory device taken along line F-F′, shown in FIG. 8A or 8B, may be the same as shown in FIG. 7B. FIG. 9 illustrates a section of the memory device taken along line G-G′, shown in FIG. 8A or 8B. Hereinafter, overlapping descriptions of components identical to those shown in FIGS. 4 and 5 will be simplified or omitted.

Referring to FIGS. 8A, 8B, and 9, a gate stack structure GST of the memory device may be partitioned by a slit SLT and may extend along the first direction DR1 and the second direction DR2, which intersect each other on a plane. The gate stack structure GST may include a plurality of conductive layers CL and a plurality of insulating layers IL, which are alternately stacked in the third direction DR3 on a lower structure 200.

A contact region 112 of the gate stack structure GST may extend in the first direction DR1 from a cell array region 111 having the same structure as shown in FIG. 4. At least one auxiliary slit ASLT may be disposed in the contact region 112 of the gate stack structure GST. The auxiliary slit ASLT may be disposed between slits SLT that are adjacent to each other in the second direction DR2. The auxiliary slit ASLT and the slit SLT may extend in the third direction DR3 to penetrate the gate stack structure GST. A filling material in the auxiliary slit ASLT and the slit SLT may include an insulating material or may further include at least one of a conductive material and a semiconductor material in addition to the insulating material.

The auxiliary slit ASLT may have a line shape extending in the first direction DR1 and may be formed to be shorter in the first direction DR1 than the slit SLT. The contact region 112 may be divided into a plurality of contact regions between the slits SLT by the auxiliary slit ASLT. In an embodiment, the contact region 112 may include a first contact region 112A and a second contact region 112B, which are adjacent to each other in the second direction DR2 with the auxiliary slit ASLT interposed therebetween.

In an embodiment, the auxiliary slit ASLT may be configured as an auxiliary slit of a first type 1ASLT, which is shown in FIG. 8A. The auxiliary slit of the first type 1ASLT may continuously extend between the first contact region 112A and the second contact region 112B.

In an embodiment, the auxiliary slit ASLT may be configured as each of a plurality of auxiliary slits of a second type 2ASLT. The plurality of auxiliary slits of the second type 2ASLT may be disposed to be spaced apart from each other between the first contact region 112A and the second contact region 112B.

Referring to FIGS. 8A, 8B, and 9, a plurality of support structures SS and a plurality of contacts CT may be disposed in a contact region 112 of the gate stack structure GST. The plurality of support structures SS may extend in the third direction DR3 to penetrate the gate stack structure GST. The plurality of contacts CT may have different lengths in the third direction DR3 and may have different maximum widths from a planar viewpoint. A maximum width of each of the plurality of contacts CT may be proportional to its corresponding length.

The plurality of support structures SS and the plurality of contacts CT may be divided into a first group disposed in the first contact region 112A and a second group disposed in the second contact region 112B.

The plurality of support structures SS may have a linear cross-sectional structure from a planar viewpoint and may have a line shape having a length in the second direction DR2. A first group of a plurality of support structures SS may be symmetrical to a second group of a plurality of support structures SS with respect to the auxiliary slit ASLT. The first group of the plurality of support structures SS may be arranged to be spaced apart from each other in the first direction DR1 in the first contact region 112A, and the second group of the plurality of support structures SS may be arranged to be spaced apart from each other in the first direction DR1 in the second contact region 112B.

A plurality of contacts CT in each of the first contact region 112A and the second contact region 112B may be alternately disposed in the first direction DR1 with the plurality of support structures SS.

Each of the plurality of contacts CT may include a contact conductive layer CTC and a contact insulating layer CTI surrounding a sidewall of the contact conductive layer CTC. Each of the plurality of support structures SS may include the first to third support structure layers 1SSF to 3SSF shown in FIG. 5. A second support structure layer (2SSF shown in FIG. 5) of each support structure SS may be used as an etch barrier, during an etching process to provide a contact hole. Accordingly, a width of each of the plurality of contacts CT in the first direction DR1 may be controlled to be equal to or smaller than a distance between support structures SS that are adjacent to each other in the first direction DR1.

A first group of a plurality of contacts CT may have a length that is different from a length of a second group of a plurality of contacts CT. The first group of the plurality of contacts CT may have a maximum width that is different from a maximum width of the second group of the plurality of contacts CT from a planar viewpoint.

In an embodiment, the plurality of contacts CT may include a first contact 1CT, a second contact 2CT, a third contact 3CT, and a fourth contact 4CT, which have different lengths in the third direction DR3. The first contact 1CT and the second contact 2CT may be included in the first group and may be disposed in the first contact region 112A of the gate stack structure GST. The third contact 3CT and the fourth contact 4CT may be included in the second group and may be disposed in the second contact region 112B of the gate stack structure GST. The third contact 3CT and the fourth contact 4CT may be formed to be longer in the third direction DR3 than the first contact 1CT and the second contact 2CT. A maximum width of each of the third contact 3CT and the fourth contact 4CT may be formed to be greater than a maximum width of each of the first contact 1CT and the second contact 2CT from a planar viewpoint. The first contact 1CT may be formed to be longer in the third direction DR3 than the second contact 2CT. A maximum width of the first contact 1CT may be formed to be greater than a maximum width of the second contact 2CT from a planar viewpoint. The third contact 3CT may be formed to be longer in the third direction DR3 than the fourth contact 4CT. A maximum width of the third contact 3CT may be formed to be greater than a maximum width of the fourth contact 4CT from a planar viewpoint.

At least one of the first contact 1CT, the third contact 3CT, and the fourth contact 4CT may be in contact with a support structure SS adjacent thereto, and the second contact 2CT may be spaced apart from a support structure SS adjacent thereto. When a contact hole for each contact CT is formed, the width to which the contact hole extends in the first direction DR1 may be suppressed by the second support structure layer 2SSF of the support structure SS. Accordingly, the number of contacts to be disposed in the length direction of the slit SLT in a limited area may be increased, and the area occupied by the contact region 112 may be reduced.

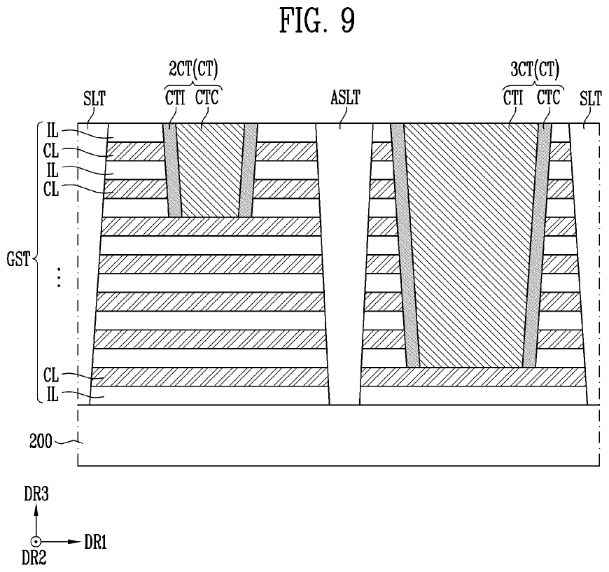

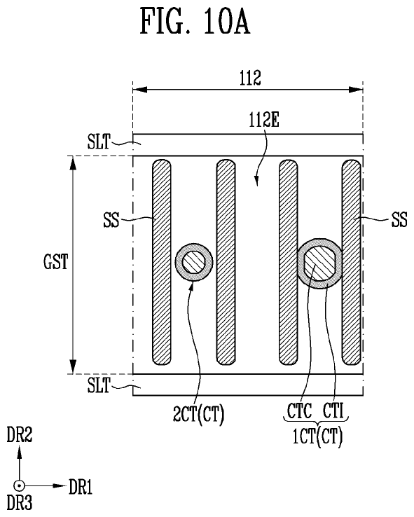

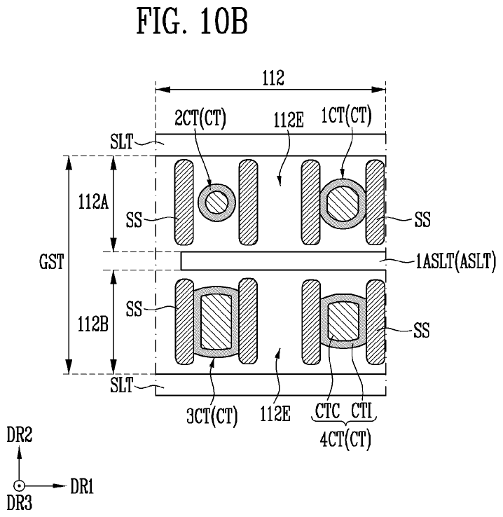

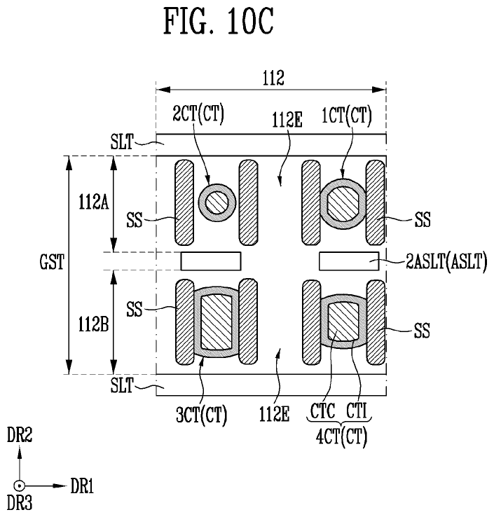

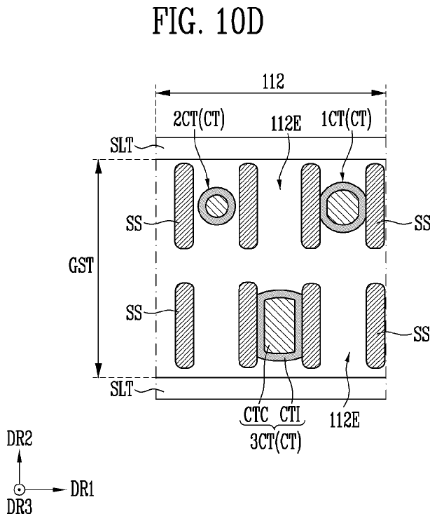

FIGS. 10A to 10D are views illustrating layouts of a memory device in accordance with embodiments of the present disclosure.

Hereinafter, overlapping descriptions of components identical to those shown in FIGS. 4 and 5 will be simplified or omitted.

A gate stack structure GST of the memory device may be partitioned by a slit SLT and may extend along the first direction DR1 and the second direction DR2, which intersect each other on a plane. The gate stack structure GST may include a plurality of conductive layers CL and a plurality of insulating layers IL, which are alternately stacked in the third direction DR3 on a lower structure 200 as shown in FIG. 5.

A contact region 112 of the gate stack structure GST may extend in the first direction DR1 from a cell array region 111 having the same structure as shown in FIG. 4. A plurality of support structures SS and a plurality of contacts CT may be disposed in the contact region 112 of the gate stack structure GST.

The plurality of support structures SS may extend in the third direction DR3 to penetrate the gate stack structure GST. The plurality of support structures SS may have a linear cross-sectional structure from a planar viewpoint and may have a line shape having a length in the second direction DR2.

Each of the plurality of contacts CT may include a contact conductive layer CTC and a contact insulating layer CTI surrounding a sidewall of the contact conductive layer CTC. The plurality of contacts CT may have different lengths in the third direction DR3 and may have different maximum widths from a planar viewpoint. A maximum width of each of the plurality of contacts CT may be proportional to its corresponding length. Each contact CT may be disposed between a pair of support structures SS which are adjacent to each other in the first direction DR1 and extend in parallel to each other.

Each of the plurality of support structures SS may include the first to third support structure layers 1SSF to 3SSF, shown in FIG. 5. A second support structure layer (2SSF shown in FIG. 5) of each support structure SS may be used as an etch barrier, during an etching process to provide a contact hole. Accordingly, a width of each of the plurality of contacts CT in the first direction DR1 may be controlled to be equal to or smaller than a distance between support structures SS that are adjacent to each other in the first direction DR1.

Each contact CT and a gate extension region 112E may be alternately disposed in the first direction DR1. The gate extension region 112E may be a region defined as the plurality of conductive layers CL and the plurality of insulating layers IL of the gate stack structure GST, shown in FIG. 5, extending between a pair of support structures SS that are adjacent to each other in the first direction DR1.

Referring to FIG. 10A, the plurality of support structures SS and the plurality of contacts CT may be arranged in a line in the first direction DR1 in the contact region 112 of the gate stack structure GST. The plurality of contacts CT may include the same first and second contacts 1CT and 2CT as described with reference to FIGS. 8A and 8B.

Referring to FIGS. 10B and 10C, at least one auxiliary slit ASLT may be disposed in the contact region 112 of the gate stack structure GST. The auxiliary slit ASLT may be disposed between slits SLT that are adjacent to each other in the second direction DR2. The auxiliary slit ASLT and the slit SLT may extend in the third direction DR3 to penetrate the gate stack structure GST. A filling material in the auxiliary slit ASLT and the slit SLT may be the same as described with reference to FIGS. 8A, 8B, and 9.

The auxiliary slit ASLT may have a line shape extending in the first direction DR1 and may be formed to be shorter in the first direction DR1 than the slit SLT. The contact region 112 may include a first contact region 112A and a second contact region 112B, which are adjacent to each other in the second direction DR2, with the auxiliary slit ASLT interposed therebetween. The auxiliary slit ASLT may be configured as an auxiliary slit of a first type 1ASLT, which is the same as described with reference to FIG. 8A or may be configured as each of a plurality of auxiliary slits of a second type 2ASLT, which are the same as described with reference to FIG. 8B.

The plurality of support structures SS and the plurality of contacts CT may be divided into a first group disposed in the first contact region 112A and a second group disposed in the second contact region 112B as described with reference to FIGS. 8A and 8B. The plurality of contacts CT may include the same first to fourth contacts 1CT to 4CT as described with reference to FIGS. 8A and 8B.

Referring to FIG. 10D, the plurality of contacts CT may be arranged in a zigzag pattern. The plurality of contacts CT may include the same first to third contacts 1CT to 3CT as described with reference to FIGS. 8A and 8B.

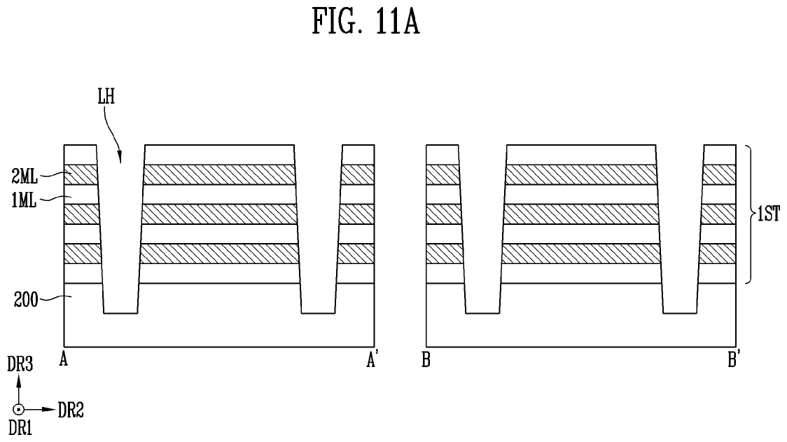

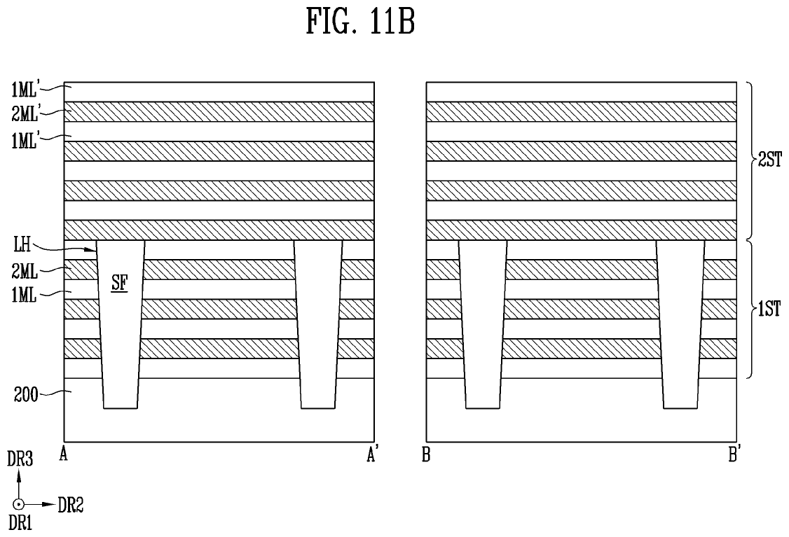

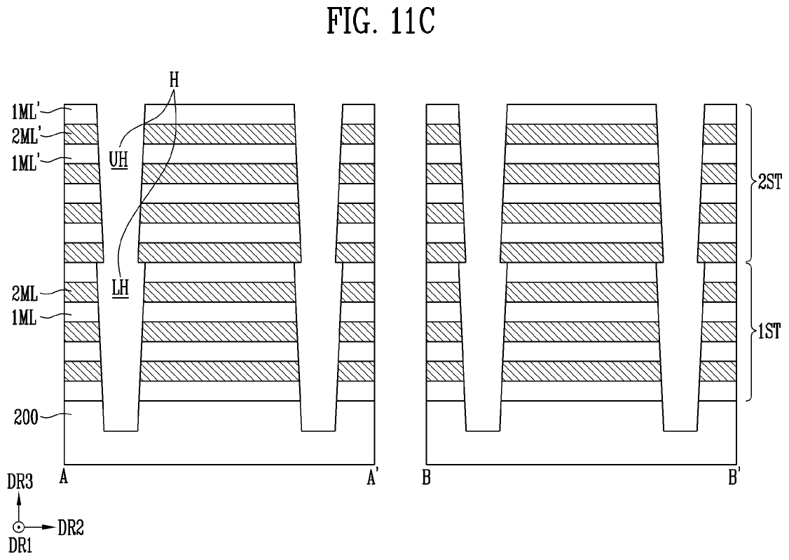

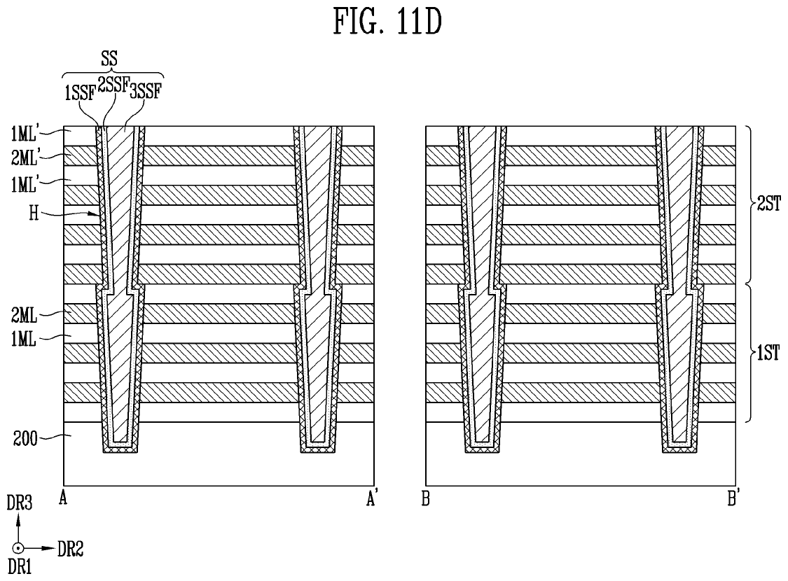

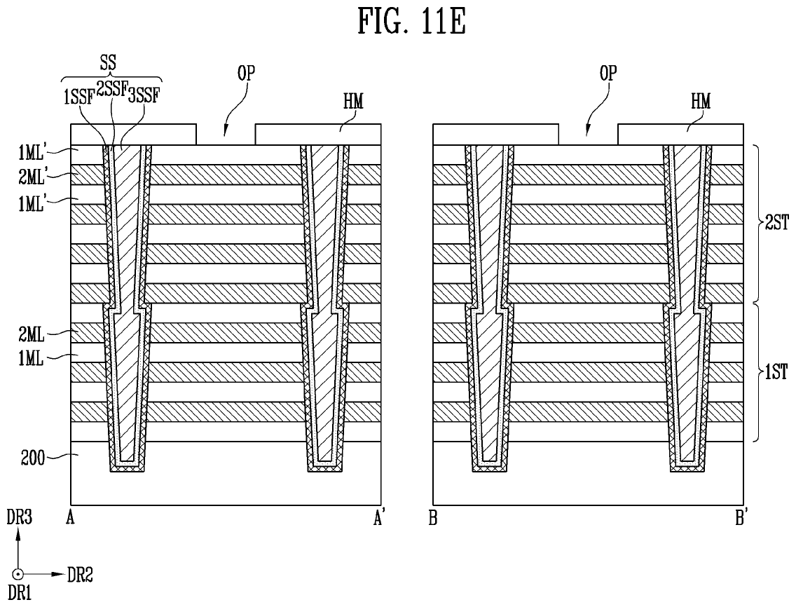

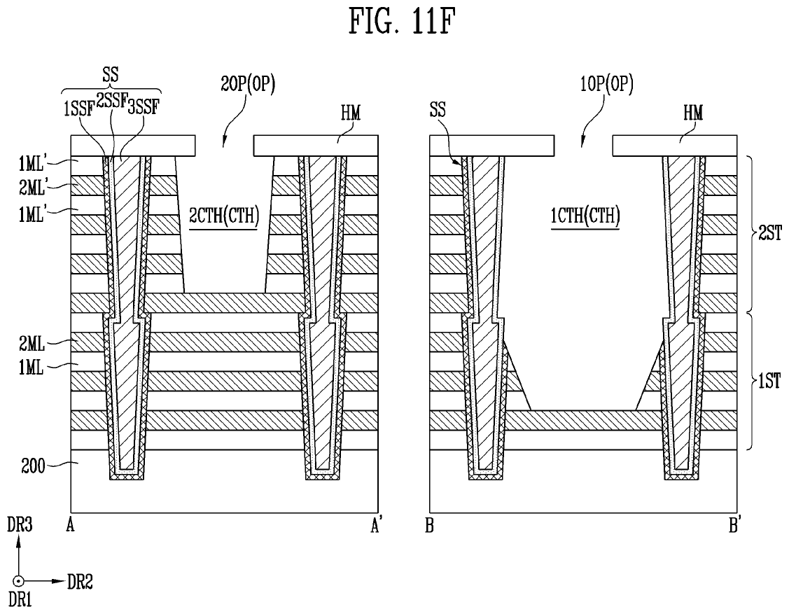

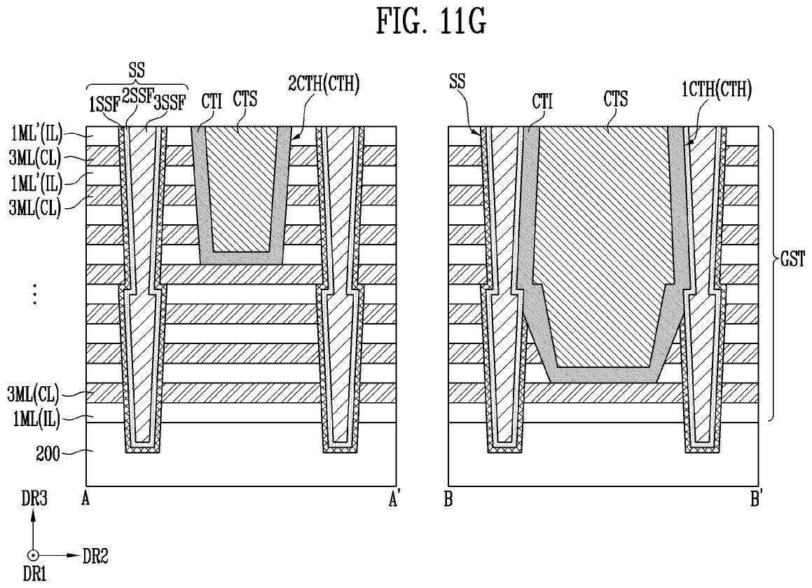

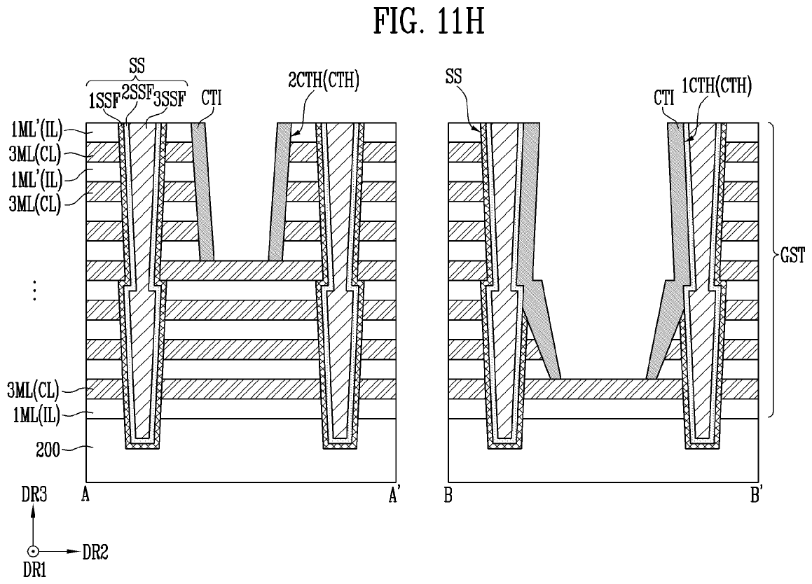

FIGS. 11A to 11I are views illustrating a manufacturing method of a memory device in accordance with an embodiment of the present disclosure.

Hereinafter, a manufacturing method of a memory device in accordance with an embodiment of the present disclosure will be described based on the contact region 112 of the gate stack structure described with reference to FIGS. 4 and 5. Hereinafter, overlapping descriptions of components identical to those shown in FIGS. 4 and 5 will be simplified or omitted.

Referring to FIG. 11A, a plurality of lower first material layers 1ML and a plurality of lower second material layers 2ML may be alternately stacked on a lower structure 200, thereby forming a first stack structure 1ST. For example, after a lower first material layer 1ML is stacked on the lower structure 200, a lower second material layer 2ML may be stacked on the lower first material layer 1ML. The plurality of lower second material layers 2ML may have an etch selectivity with respect to the plurality of lower first material layers 1ML. For example, in a subsequent selective etching process, the etch rate of the plurality of lower second material layers 2ML may be greater than that of the plurality of lower first material layers 1ML. In an embodiment, the lower first material layer 1ML may include oxide, such as a silicon oxide layer, and the lower second material layer 2ML may include nitride, such as a silicon nitride layer.

After the first stack structure 1ST is formed, a plurality of lower holes LH may be formed, which penetrate the first stack structure 1ST. Portions of the plurality of lower first material layers 1ML and the plurality of lower second material layers 2ML of the first stack structure 1ST may be etched to form the plurality of lower holes LH. The plurality of lower first material layers 1ML and the plurality of lower second material layers 2ML may be exposed through an inner wall of each lower hole LH. The lower structure 200 may be exposed through the bottom of each lower hole LH.

Referring to FIG. 11B, a sacrificial layer SF may be formed in the plurality of lower holes LH. The sacrificial layer SF may include a material having an etch selectivity with respect to the plurality of lower first material layers 1ML and the plurality of lower second material layers 2ML. In an embodiment, the sacrificial layer SF may include a conductive material. For example, the sacrificial layer SF may include tungsten. A plurality of upper first material layers 1ML′ and a plurality of upper second material layers 2ML′ may be alternately stacked on the first stack structure 1ST in which the sacrificial layer SF is formed, thereby forming a second stack structure 2ST. The plurality of upper first material layers 1ML′ may be formed of the same material as the plurality of lower first material layers 1ML, and the plurality of upper second material layers 2ML′ may be formed of the same material as the plurality of lower second material layers 2ML.

Referring to FIGS. 11C, a plurality of upper holes UH may be formed, which penetrate the second stack structure 2ST. Portions of the plurality of upper first material layers 1ML′ and the plurality of upper second material layers 2ML′ may be etched to form the plurality of upper holes UH. Subsequently, the sacrificial layer SF formed in the plurality of lower holes LH may be selectively removed through the plurality of upper holes UH. The plurality of upper holes UH may be respectively connected to the plurality of lower holes LH, and accordingly, a plurality of holes H may be defined. Each hole H may include an upper hole UH and a lower hole LH, which are connected to each other.

Although a process of forming a hole H inside a double stack structure including the first and second stack structures 1ST and 2ST has been described in FIGS. 11A to 11C, the embodiment of the present disclosure is not limited thereto. In an embodiment, after a plurality of first material layers and a plurality of material layers are formed by a number of layers corresponding to a target, the hole H may be formed to penetrate the layers. In another embodiment, the hole H may be formed to penetrate three or more multi-layer stack structures.

Referring to FIG. 11D, a plurality of support structures SS may be formed in the plurality of holes H. The process of forming each support structure SS may include a process of forming a first support structure layer 1SSF, a process of forming a second support structure layer 2SSF, and a process of forming a third support structure layer 3SSF. In an embodiment, the first support structure layer 1SSF may be formed along inner walls of the plurality of holes H. The second support structure layer 2SSF may be formed along an inner wall of the first support structure layer 1SSF in the plurality of holes H. The third support structure layer 3SSF may be formed along an inner wall of the second support structure layer 2SSF in the plurality of holes H. The first to third support structure layers 1SSF to 3SSF may include the materials described with reference to FIG. 5.

Referring to FIG. 11E, a hard mask HM may be formed on the second stack structure 2ST. The hard mask HM may include a plurality of openings OP that are spaced apart from each other. The plurality of openings OP may define an arrangement region of a plurality of contact holes CTH shown in FIG. 11F. A layout of the plurality of openings OP may be variously designed according to a layout of contacts corresponding to a target.

Referring to FIG. 11F, portions of the plurality of upper first material layers 1ML′, the plurality of upper second material layers 2ML′, the plurality of lower first material layers 1ML, and the plurality of lower second material layers 2ML may be etched through the plurality of openings OP of the hard mask HM, thereby forming the plurality of contact holes CTH. An etching process may be controlled such that a plurality of upper second material layers 2ML′ and a plurality of lower second material layers 2ML are individually exposed through the bottoms of the plurality of contact holes CTH. Accordingly, the plurality of contact holes CTH may be formed to different depths. In an embodiment, the plurality of contact holes CTH may include a first contact hole 1CTH and a second contact hole 2CTH. The first contact hole 1CTH may be formed deeper than the second contact hole 2CTH.

The plurality of contact holes CTH may be sequentially formed for each depth. In an embodiment, an etching process for forming the first contact hole 1CTH and an etching process for forming the second contact hole 2CTH may be individually performed. For example, the plurality of openings OP may include a first opening 10P corresponding to the first contact hole 1CTH and a second opening 20P corresponding to the second contact hole 2CTH. The second stack structure 2ST may be etched such that the second contact hole 2CTH is formed through the first opening 10P and the second opening 20P. Subsequently, an etch barrier pattern may be formed, which blocks the second opening 20P and the second contact hole 2CTH and exposes the first opening 10P. After that, the second stack structure 2ST and the first stack structure 1ST may be additionally etched such that the first contact hole 1CTH is formed through the first opening 10P.

According to the above-described process, the arrangement position of the plurality of contact holes CTH may be controlled as a position corresponding to a target through the plurality of openings OP. Accordingly, an alignment error of the plurality of contact holes CTH may be reduced.

The second support structure layer 2SSF of the support structure SS may include a material having an etch selectivity with respect to the plurality of lower first material layers 1ML, the plurality of lower second material layers 2ML, the plurality of upper first material layers 1ML′, and the plurality of upper second material layers 2ML′. Accordingly, the second support structure layer 2SSF of the support structure SS may be used as an etch barrier layer during an etching process for forming the plurality of contact holes CTH. Therefore, although a width of the contact hole CTH is expanded as compared with a width of the opening OP during the etching process for forming the contact holes CTH, the expansion range of the width of the contact hole CTH may be limited by the second support structure layer 2SSF. In an embodiment, the second contact hole 2CTH may be formed at a position that is spaced apart from the plurality of support structures SS, and the first contact hole 1CTH may expose at least one of the plurality of support structures SS. In the etching process for forming the first contact hole 1CTH, the first support structure layer 1SSF may be etched, but the width of the first contact hole 1CTH may be limited to a distance between support structures SS that are adjacent to each other as the second support structure layer 2SSF serves as the etch barrier layer.

In accordance with the embodiment of the present disclosure, the second support structure layer 2SSF may be used as the etch barrier layer, and thus the width of the contact hole CTH may be mitigated or prevented from being excessively wide.

Referring to FIGS. 11G, a contact insulating layer CTI may be formed along inner walls of the plurality of contact holes CTH. A contact sacrificial layer CTS may be formed on the contact insulating layer CTI. The contact sacrificial layer CTS may fill a central region of each of the plurality of contact holes CTH. The contact sacrificial layer CTS may include a conductive material or an insulating material and may have an etch selectivity with respect to the contact insulating layer CTI. For example, the contact sacrificial layer CTS may include tungsten. The hard mask HM shown in FIG. 11F may be removed after the contact sacrificial layer CTS is formed.

After that, the plurality of lower second material layers 2ML and the plurality of upper second material layers 2ML′, which are shown in FIG. 11F, may be replaced with a plurality of third material layers 3ML. In an embodiment, the process of replacing the plurality of lower second material layers 2ML and the plurality of upper second material layers 2ML′, which are shown in FIG. 11F, with the plurality of third material layers 3ML, shown in FIG. 11G, may be performed through a slit or may be performed through the slit and an auxiliary slit. The slit may be formed with the same layout as the slit SLT, shown in at least one of FIGS. 4, 6, 7A, 8A, 8B, and 10A to 10D, and may penetrate the first stack structure 1ST and the second stack structure 2ST, which are shown in FIG. 11F. The auxiliary slit may be formed with the same layout as the auxiliary slit ASLT, shown in FIGS. 8A, 8B, 10B, and 10C, and may penetrate the first stack structure 1ST and the second stack structure 2ST, which are shown in FIG. 11F.

The above-described replacement process may include a process of forming a plurality of recess regions by removing the plurality of lower second material layers 2ML and the plurality of upper second material layers 2ML′ and a process of filling the plurality of recess regions respectively with the plurality of third material layers 3ML. The plurality of recess regions and the plurality of third material layers 3ML may be formed through the slit or may be formed through the slit and the auxiliary slit.

The plurality of third material layers 3ML may be individually connected to the plurality of contact holes CTH. The plurality of third material layers 3ML may be used as the plurality of conductive layers CL described with reference to FIG. 5, and the plurality of remaining lower first material layers 1ML and the plurality of remaining upper first material layers 1ML′ may be used as the plurality of insulating layers IL described with reference to FIG. 5. Accordingly, a gate stack structure GST may be formed, which includes a plurality of conductive layers CL and a plurality of insulating layers IL.

Referring to FIG. 11H, the contact sacrificial layer CTS, shown in FIG. 11G, may be selectively removed. Subsequently, a portion of the contact insulating layer CTI may be etched such that the bottoms of the plurality of contact holes CTH are opened. The plurality of third material layers 3ML may be individually exposed through the bottoms of the plurality of contact holes CTH.

Referring to FIG. 11I, a plurality of contact conductive layers CTC may be formed in the plurality of contact holes CTH. Each contact conductive layer CTC may be formed along an inner wall of a contact insulating layer CTI corresponding thereto. The plurality of contact conductive layers CTC may be individually connected to the plurality of third material layers 3ML.

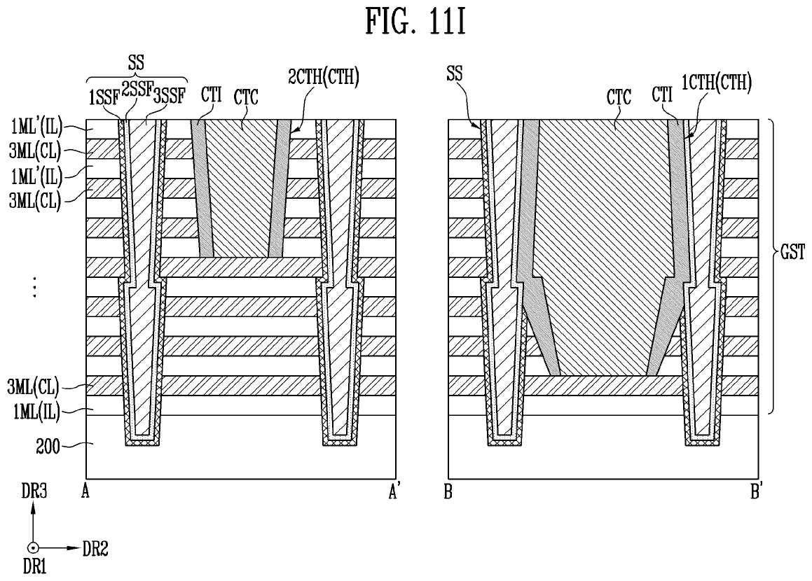

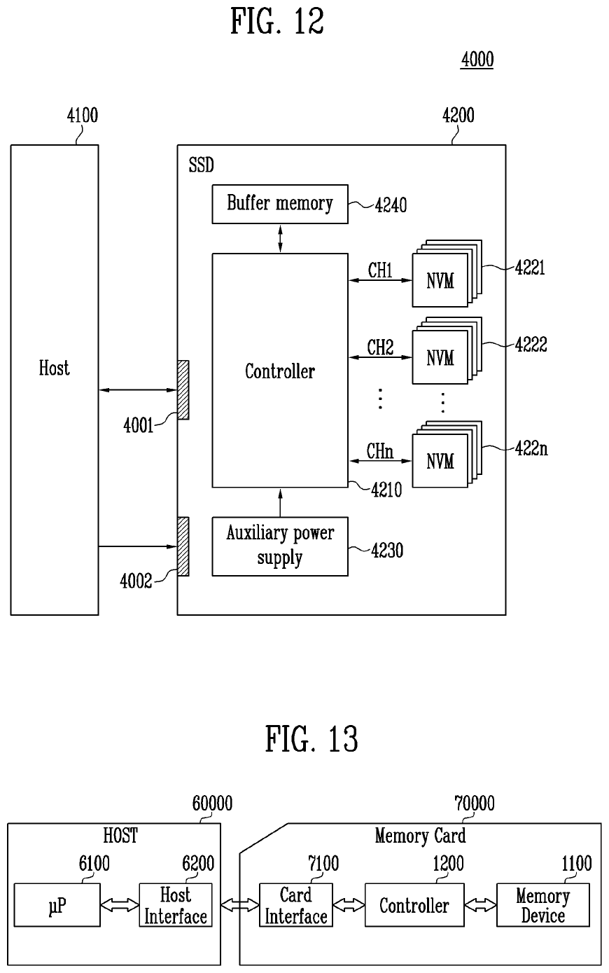

FIG. 12 is a diagram illustrating a Solid-State Drive (SSD) system to which the memory device of the present disclosure is applied.

Referring to FIG. 12, a SSD system 4000 may include a host 4100 and an SSD 4200. The SSD 4200 may exchange a signal with the host 4100 through a signal connector 4001 and may be supplied with power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. Exemplarily, the signal may be transmitted based on an interface between the host 4100 and the SSD 4200. For example, the signal may be defined by at least one interface, such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 4221 to 422n may include a plurality of memory cells configured to store data. Each of the plurality of memory devices 4221 to 422n may be configured identically to at least one of the memory devices described with reference to FIGS. 4 to 10D. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive power PWR input from the host 4100 and charge the power PWR. When the supply of power from the host 4100 is not smooth, the auxiliary power supply 4230 may provide power to the SSD 4200. Exemplarily, the auxiliary power supply 4230 may be located in the SSD 4200 or may be located outside of the SSD 4200. For example, the auxiliary power supply 4230 may be located on a main board and may provide auxiliary power to the SSD 4200.

The buffer memory 4240 may be used as a buffer memory of the SSD 4200. For example, the buffer memory 4240 may temporarily store data received from the host 4100 or data received from the plurality of memory devices 4221 to 422n, or temporarily store meta data (e.g., a mapping table) of the plurality of memory devices 4221 to 422n. The buffer memory 4240 may include volatile memory, such as DRAM, SDRAM, DDR SDRAM, LPDDR SDRAM, and GRAM or nonvolatile memory, such as FRAM, ReRAM, STT-MRAM, and PRAM.

FIG. 13 is a diagram illustrating a memory card system to which the memory device of the present disclosure is applied.

Referring to FIG. 13, a memory system 70000 may be implemented as a memory card or a smart card. The memory system 70000 may include a memory device 1100, a controller 1200, and a card interface 7100.

The controller 1200 may control data exchange between the memory device 1100 and the card interface 7100. In some embodiments, the card interface 7100 may be a secure digital (SD) card interface or a multi-media card (MMC) interface, but the present disclosure is not limited thereto.

The card interface 7100 may interface data exchange between a host 60000 and the controller 1200 according to a protocol of the host 60000. In some embodiments, the card interface 7100 may support a universal serial bus (USB) protocol and an inter-chip (IC)-USB protocol. The card interface 7100 may mean hardware capable of supporting a protocol used by the host 60000, software embedded in the hardware, or a signal transmission scheme.

When the memory system 70000 is connected to a host interface 6200 of the host 60000, such as a PC, a tablet PC, a digital camera, a digital audio player, a cellular phone, console video game hardware, or a digital set-top box, the host interface 6200 may perform data communication with the memory device 1100 through the card interface 7100 and the controller 1200 under the control of a microprocessor (μP) 6100.

In accordance with the present disclosure, structural stability of a memory device may be improved.

What is claimed is:

1. A memory device comprising:
a gate stack structure including a plurality of insulating layers and a plurality of conductive layers, which are alternately stacked;
a plurality of support structures extending in a stacked direction, the stacked direction being a direction in which the plurality of insulating layers and the plurality of conductive layers are stacked;
a plurality of contact holes penetrating at least one of the plurality of conductive layers and the plurality of insulating layers, the plurality of contact holes, extending in the stacked direction, being formed to have different lengths to individually expose the plurality of conductive layers disposed at different levels; and
a plurality of contacts disposed in the plurality of contact holes to be individually connected to the plurality of conductive layers,
wherein the plurality of contact holes include a first contact hole exposing a sidewall of at least one of the plurality of support structures and a second contact hole that is spaced apart from the plurality of support structures.

2. The memory device of claim 1, wherein each of the plurality of contact holes is disposed between corresponding support structures that are adjacent to each other, among the plurality of support structures, and
wherein the plurality of contact holes have a larger width as the length in the stacked direction is longer.

3. The memory device of claim 2, wherein the first contact hole is formed with a length that is longer in the stacked direction than a length of the second contact hole, and
wherein a maximum width of the first contact hole is greater than a maximum width of the second contact hole.

4. The memory device of claim 1, wherein each of the plurality of support structure includes:
a first support structure layer; and
a second support structure layer extending along an inner wall of the first support structure layer, the second support structure layer including a material that is different from a material of the first support structure layer.

5. The memory device of claim 4, wherein the first support structure layer includes an insulating material, and
wherein the second support structure layer includes a metal nitride layer.

6. The memory device of claim 4, wherein the second support structure layer is exposed by the first contact hole.

7. The memory device of claim 4, wherein each of the plurality of support structures further includes a third support structure layer surrounded by the second support structure layer.

8. The memory device of claim 7, wherein the first to third support structure layers include different materials.

9. The memory device of claim 7, wherein the third support structure layer includes a conductive material.

10. The memory device of claim 7, wherein each of the plurality of contact holes is disposed to be spaced apart from the third support structure layer with the second support structure layer interposed therebetween.

11. The memory device of claim 1, wherein each of the first contact hole and the second contact hole includes a lower region and an upper region extending in the stacked direction,
wherein a width of the upper region is greater than a width of the lower region in each of the first contact hole and the second contact hole,
wherein the upper region of the first contact hole exposes the sidewall of at least one of the plurality of support structures,
wherein the upper region of the second contact hole is disposed to be spaced apart from the plurality of support structures, and
wherein the lower region of each of the first contact hole and the second contact hole is disposed to be spaced apart from the plurality of support structures.

12. The memory device of claim 1, wherein the plurality of support structures include at least one of a support structure of a first type and a support structure of a second type, and
wherein the support structure of the first type includes a circular cross-section, and
wherein the support structure of the second type is formed in a line shape.

13. The memory device of claim 1, further comprising slits defined along both sidewalls of the gate stack structure while penetrating the plurality of insulating layers and the plurality of conductive layers,
wherein the slits extend in a first direction and are spaced apart from each other in a second direction that is perpendicular to the first direction.

14. The memory device of claim 13, wherein the plurality of support structures include a first linear support structure and a second linear support structure, which are spaced apart from each other with the first contact hole interposed therebetween.

15. The memory device of claim 14, wherein the first linear support structure and the second linear support structure extend in the first direction and are spaced apart from each other in the second direction.

16. The memory device of claim 14, wherein the first linear support structure and the second linear support structure extend in the second direction and are spaced apart from each other in the first direction.

17. The memory device of claim 1, further comprising a linear auxiliary slit penetrating the gate stack structure, the linear auxiliary slit extending in the first direction,
wherein the gate stack structure includes a first contact region and a second contact region at both sides of the auxiliary slit.

18. The memory device of claim 17, wherein the plurality of contacts include:
a first group disposed in the first contact region; and
a second group disposed in the second contact region, the second group having a maximum width that is different from a maximum width of the first group.

19. A memory device comprising:
a gate stack structure including a plurality of insulating layers and a plurality of conductive layers, which are alternately stacked;
a plurality of support structures penetrating the plurality of insulating layers and the plurality of conductive layers;
a first contact conductive layer in contact with a conductive layer, among the plurality of conductive layers; and
a first contact insulating layer surrounding a sidewall of the first contact conductive layer,
wherein the plurality of support structures include a first support structure in contact with the first contact insulating layer.

20. The memory device of claim 19, wherein each of the plurality of support structures includes:
a first support structure layer extending along an inner wall of a hole penetrating the plurality of insulating layers and the plurality of conductive layers;
a second support structure layer disposed in the hole, the second support structure layer extending along an inner wall of the first support structure layer; and
a third support structure layer disposed in the hole, the third support structure layer extending along an inner wall of the second support structure layer, and
wherein the first contact insulating layer is in contact with the second support structure layer of the first support structure.

21. The memory device of claim 20, wherein the first support structure layer includes an insulating material, and
wherein the second support structure layer includes a material having an etch selectivity with respect to a silicon oxide layer and a silicon nitride layer.

22. The memory device of claim 20, wherein the first support structure layer includes an oxide layer,
wherein the second support structure layer includes a metal nitride layer, and
wherein the third support structure layer includes a metal layer.

23. The memory device of claim 19, wherein the plurality of support structures include a second support structure,
wherein the first support structure and the second support structure are formed in line shapes extending in parallel to each other, and
wherein the first contact conductive layer and the first contact insulating layer are disposed between the first support structure and the second support structure.

24. The memory device of claim 23, wherein the first contact insulating layer is in contact with the second support structure.

25. The memory device of claim 19, wherein the plurality of support structures further include a plurality of second support structures,
wherein each of the plurality of second support structures and the first support structures has a circular cross-section, and
wherein the plurality of second support structures include two or more second support structures arranged to be spaced apart from each other along an outer wall of the first contact insulating layer and being in contact with the first contact insulating layer.

26. The memory device of claim 19, further comprising a slit partitioning the gate stack structure while penetrating the plurality of insulating layers and the plurality of conductive layers,
wherein the slit is formed in a line shape extending in a first direction.

27. The memory device of claim 26, further comprising a second support structure facing the first support structure,
wherein a first contact including the first contact conductive layer and the first contact insulating layer is disposed between the first support structure and the second support structure.

28. The memory device of claim 27, wherein each of the first support structure and the second support structure is formed in a line shape extending in the first direction or a second direction that is perpendicular to the first direction.
